(19) United States
(12) Patent Application Publication
(10) Pub. No.: US 2025/0199201 A1
(43) Pub. Date: Jun. 19, 2025

(54) ULTRAFAST META-MAGNETIC NANOSTRUCTURES WITH HELICITY-DEPENDENT SWITCHING

(71) Applicant: The Regents of the University of California, Oakland, CA (US)

(72) Inventors: Abdoulaye Ndao, La Jolla, CA (US); Muhammad Waleed Khalid, San Diego, CA (US); Jeongho Ha, La Jolla, CA (US)

(21) Appl. No.: 18/988,266

(22) Filed: Dec. 19, 2024

Related U.S. Application Data
(60) Provisional application No. 63/612,267, filed on Dec. 19, 2023.

(51) Int. Cl. G02B 1/00; G01R 33/00; H10B 61/00; H10N 50/80

(52) U.S. Cl. CPC G02B 1/002; G01R 33/0088; H10B 61/22; H10N 50/80

(57) ABSTRACT

Disclosed are methods, systems, and devices related to optical helicity-dependent switching of monolithic multilayer nanostructures in a variety of geometries using femtosecond meta-circularly polarized optical pulses at ambient temperature. In an example embodiment, a method for switching magnetization is provided. The method includes: receiving by a metasurface, positioned on a first side of a substrate and comprising a plurality of nanostructured resonators, one or more linearly-polarized femtosecond optical pulses; receiving by a magnetic medium, positioned on a second side of the substrate opposite to the first side, the RCP light or the LCP light, after traversing through the substrate, at one or more locations of the magnetic medium; and selectively inverting a magnetization of the magnetic medium at the one or more locations based on the receiving of the RCP light or the LCP light by the magnetic medium.

### CROSS-REFERENCE TO RELATED APPLICATION

This patent document claims priority to and benefits of U.S. Provisional Application No. 63/612,267, entitled “ULTRAFAST META-MAGNETIC NANOSTRUCTURES WITH HELICITY-DEPENDENT SWITCHING,” and filed on Dec. 19, 2023. The entire content of the above noted patent application is incorporated by reference as part of the disclosure of this patent document.

### TECHNICAL FIELD

This patent document is generally related to techniques to deterministically switch magnetization in magnetic materials.

### BACKGROUND

It has been demonstrated that magnetization can be controlled and switched on/off at ultrafast speeds using femtosecond laser pulses. This technique has applications in information processing and memory storage devices using optics for next-generation computing. However, integrating optical helicity-dependent switching into practical devices has been challenging due to the need for very precise nanostructured optical components. The disclosed embodiments can be implemented to achieve optical helicity-dependent switching in various data processing and storage technologies.

### SUMMARY

The disclosed embodiments, among other features and benefits, relate to methods, systems, and apparatus for optical helicity-dependent switching of multilayer nanostructures in a variety of geometries using femtosecond meta-circularly polarized optical pulses at ambient temperature. The disclosed embodiments enable deterministic magnetization switching in magnetic materials using metasurfaces.

In one aspect, a magnetic memory device is disclosed. The magnetic memory device comprises: a substrate; a magnetic medium; and a metasurface comprising a plurality of nanostructured resonators, wherein: the metasurface is positioned on a first side of the substrate, the magnetic medium is positioned on a second side of the substrate opposite to the first side, the substrate, the magnetic medium and the metasurface form a monolithic structure, the metasurface is configured to receive one or more linearly-polarized femtosecond optical pulses, a first portion of the plurality of nanostructured resonators is configured to produce right circularly polarized (RCP) light upon illumination by the one or more linearly-polarized femtosecond optical pulses, a second portion of the plurality of nanostructured resonators is configured to produce left circularly polarized (LCP) light upon illumination by the one or more linearly-polarized femtosecond optical pulses, and the magnetic medium is configured to receive the RCP light or the LCP light, after traversing through the substrate, at one or more locations of the magnetic medium to enable selective inverting of a magnetization of the magnetic medium at the one or more locations.

In another aspect, a method for switching magnetization is disclosed. The method comprises: receiving by a metasurface, positioned on a first side of a substrate and comprising a plurality of nanostructured resonators, one or more linearly-polarized femtosecond optical pulses; receiving by a magnetic medium, positioned on a second side of the substrate opposite to the first side, the RCP light or the LCP light, after traversing through the substrate, at one or more locations of the magnetic medium; and selectively inverting a magnetization of the magnetic medium at the one or more locations based on the receiving of the RCP light or the LCP light by the magnetic medium. In some implementations, a first portion of the plurality of nanostructured resonators is configured to produce right circularly polarized (RCP) light upon illumination by the one or more linearly-polarized femtosecond optical pulses, and a second portion of the plurality of nanostructured resonators is configured to produce left circularly polarized (LCP) light upon illumination by the one or more linearly-polarized femtosecond optical pulses.

These, and other, aspects are described in the present document.

### BRIEF DESCRIPTION OF THE DRAWINGS

FIG. 1 shows a schematic of an example monolithic device based on the disclosed technology.

FIG. 2A shows a diagram of an example metasurface unit cell based on the disclosed technology.

FIG. 2B shows exemplary broadband simulation data of a metasurface based on the disclosed technology.

FIG. 2C shows a plot of example electric field components inside a metasurface based on the disclosed technology.

FIG. 2D shows a scanning electron microscope (SEM) image of an example m-QWP based on the disclosed technology.

FIG. 2E shows an SEM image of another example m-QWP based on the disclosed technology.

FIG. 2F shows example polarization ellipses for an ideal, a simulated, and a fabricated m-QWP based on the disclosed technology.

FIG. 2G shows an additional example of polarization ellipses for an ideal, a simulated, and a fabricated m-QWP based on the disclosed technology.

FIG. 3A shows the structure of an example magnetic medium that can be implemented in accordance with the disclosed technology.

FIG. 3B shows example hysteresis loops that can be obtained for out-of-plane magnetization of a magnetic sample in accordance with implementations of the disclosed technology.

FIG. 3C shows additional example hysteresis loops that can be obtained for out-of-plane magnetization of a magnetic sample in accordance with implementations of the disclosed technology.

FIG. 4A shows a schematic of three example monolithic configurations based on the disclosed technology which were utilized in an example study carried out in accordance with the disclosed techniques.

FIG. 4B shows example images that can be obtained using monolithic configurations shown in FIG. 4A.

FIG. 4C shows additional example images that can be obtained using monolithic configurations shown in FIG. 4A.

FIG. 5A shows an example image obtained in accordance with optical switching techniques based on the disclosed technology.

FIG. 5B shows another example image obtained in accordance with optical switching techniques based on the disclosed technology.

FIG. 6 shows a flow diagram illustrating an example method based on the disclosed technology.

### DETAILED DESCRIPTION

Advancements in ultrafast optical switching, particularly in the deterministic control of magnetic material characteristics through femtosecond circularly polarized light pulses, have been driven by the rising desire for quick and dense information storage. However, it has proven difficult to achieve monolithic optical helicity-dependent switching in ambient circumstances.

Various embodiments that enable optical helicity-dependent switching are disclosed herein including a monolithic multilayer nanostructure that enables optical helicity-dependent switching in a variety of geometries using femtosecond meta-circularly polarized optical pulses at ambient temperature. Metasurfaces, which are extremely thin optical structures, have recently come into prominence as potent instruments for precise electromagnetic field control at subwavelength scales. The disclosed embodiments include optical metasurface devices capable of monolithic optical helicity-dependent magnetic switching. Such a device is compatible with complementary metal-oxide semiconductor (CMOS) fabrication techniques and can operate at ambient environmental conditions, which are crucial factors for scaling up to real-world practical devices. The disclosed embodiments find applications in, for example, opto-magnetic data processing, storage, and memory technologies. Other example applications of the disclosed embodiments include information technology, spintronics, sensing, and enhanced memory.

Ultrafast optical manipulation of magnetization has experienced developments over the last two decades, launched by the first demonstration of the ultrafast manipulation of magnetization using femtosecond laser pulses and then the control of the magnetic order known as all-optical switching (AOS). The deterministic magnetization switching using circularly polarized laser pulses is commonly known as all-optical helicity-dependent switching (AO-HDS), in which the helicity of the input polarization of the electromagnetic wave determines the final state of the magnetization. Despite AO-HDS being successfully demonstrated in both ferri- and ferro-magnetic thin films, the mechanism of this process is still a topic of debate in the scientific community. Several models have been presented to explain AO-HDS. These include local effective fields created by the circularly polarized light via the inverse Faraday effect as a source for magnetic switching. In contrast, the transfer of spin angular momentum from light to the magnetic material and magnetic circular dichroism (MCD) have also been modeled to explain AO-HDS. However, recent experiments have pointed to the fact that a contributing or even dominant mechanism of AO-HDS in ferromagnetic materials is MCD. In MCD, one magnetic domain orientation favors the absorption of light with a particular helicity over the other, and temperature gradient across domain walls or difference of temperature of individual grains, induced by the differential absorption, switches the magnetization.

AO-HDS opens the way to manipulating the magnetization at ultrafast speeds for applications in information processing and memory storage devices using optics. However, the monolithic high-density of optical helicity-dependent switching has remained inaccessible as its high density of elements necessitates nanostructured optical components. Metasurfaces, emerging from the broader field of metamaterials, have demonstrated many conventional and novel functionalities while being only sub-wavelength thick. Compared with traditional optical components, the unique planar configuration, large-scale integration, and CMOS processing compatibility of metasurfaces make them well-suited to monolithic integration with optical switching structures, as described herein.

In the description that follows, techniques to achieve monolithic optical helicity-dependent magnetic switching enabled by metasurfaces are disclosed and experimentally demonstrated. The disclosed techniques offer the first monolithic integration of optical helicity-dependent magnetic switching and leverage ultrafast magnetism and metasurfaces. The disclosed monolithic meta-magnetic platforms provide a practical route for integrating optical helicity-dependent switching with complex systems, holding great promise for cutting-edge applications in information, memory, and storage devices.

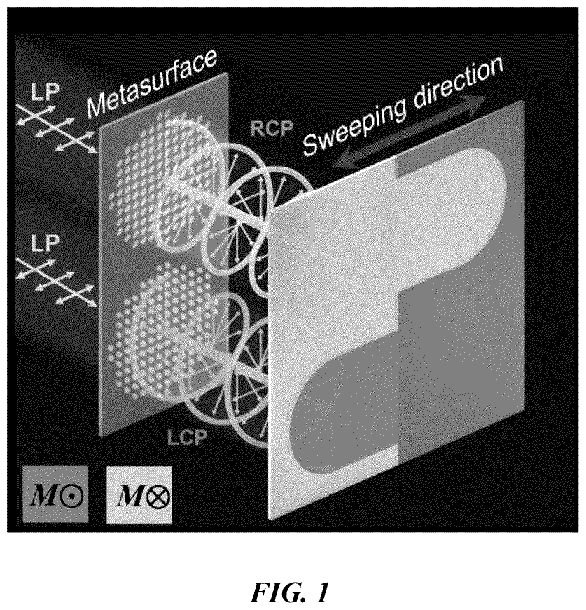

In one example embodiment, an all-dielectric metasurface to generate circularly polarized (CP) pulses capable of AO-HDS in a magnetic structure comprising a [Co/Pt] ferromagnetic thin film is disclosed. FIG. 1 shows an example of such a meta-magnetic platform which includes a metasurface quarter-wave plate (m-QWP) to generate circularly polarized light and a multilayer ferromagnetic thin film [Co/Pt]_{N}, where N represents the number of bilayers in the magnetic multilayer structure. As shown therein, a linearly polarized (LP) beam is incident upon the metasurface. Magnetic domains in the multilayer ferromagnetic thin film are shown far right in dark and light grey. The dark grey domains represent out-of-plane magnetization pointing “up” (M⊙) and the light grey domains represent out-of-plane magnetization pointing “down” (M⊗). Right circular polarization (RCP) and left circular polarization (LCP) laser pulses generated by the all-dielectric metasurface can induce optical switching. The orientation of the nanoparticles determines the direction of the circular polarization. FIG. 1 depicts the metasurface and the multilayer ferromagnetic thin film as being spaced apart from one another for demonstration purposes only. In actual implementations, the metasurface and the multilayer ferromagnetic thin film (sometimes referred to herein as the storage medium) can be disposed on respective faces of a common dielectric substrate, forming a monolithic structure. In some implementations, the metasurface is disposed on a first surface of the dielectric substrate and the multilayer ferromagnetic thin film is disposed on a second surface of the dielectric substrate that opposes the first surface. Due to the perpendicular interfacial magnetic anisotropy in the multilayer ferromagnetic thin film, the film is perpendicularly magnetized. Therefore, the contrast observed in some of the example images described herein results from the two possible magnetization directions. The laser pulse helicity that is incident on the storage medium is determined by the resonator orientation of the m-QWP to produce either RCP or LCP. This enables the selective inversion of only one type of magnetization orientation while the other magnetization orientation remains dormant.

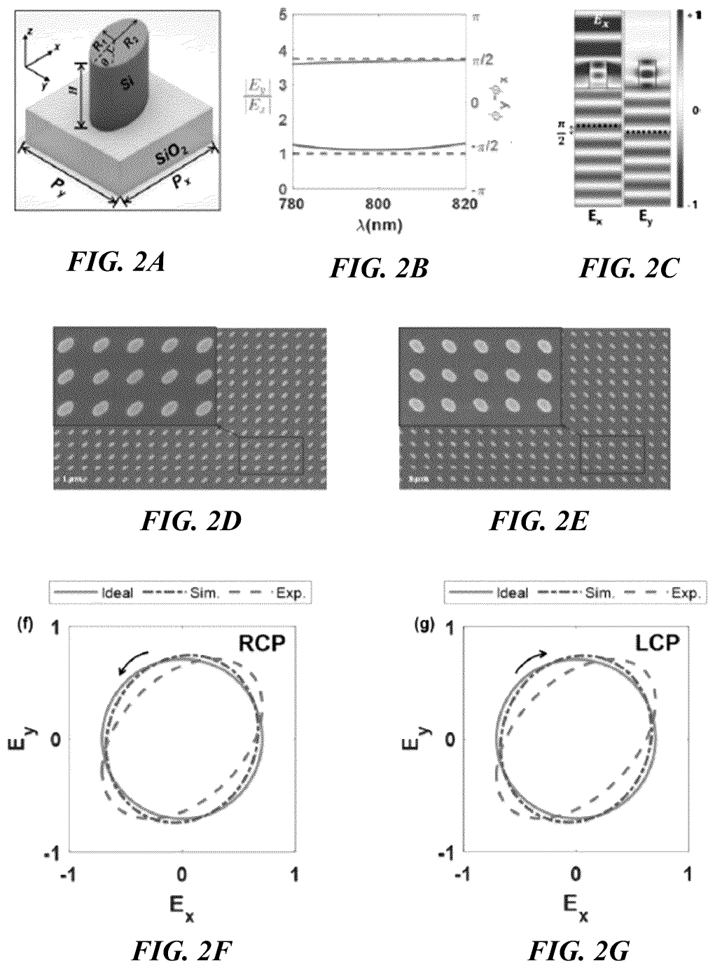

In the above example embodiment, the m-QWP comprises an array of amorphous silicon (α-Si) elliptical resonators deposited on a fused-silica substrate acting as a two-dimensional birefringent material. FIG. 2A shows an example diagram of the α-Si metasurface unit cell and its optimized geometric parameters: R₁₌₆₀ nm, R₂₌₁₁₀ nm, H=385 nm, and Pₓ=P_{y}=400 nm, where R₁ represents the semi-minor axis of the resonator, R₂ represents the semi-major axis of the resonator, H represents the height of the resonator, and Pₓ and P_{y} represent the periodicity of the resonators in the array in the mutually perpendicular x and y directions as shown in FIG. 2A. These parameters satisfy the Kerker condition to maximize the measured transmission, >97% of the incident electric field. The angle of rotation of the resonator with respect to the x-axis is θ=±45° depending on the desired helicity of light. θ=+45° gives RCP and the 0=−45° gives LCP at the output of the metasurface. Due to the anisotropy of the resonator, the metasurface in this example embodiment works for LP polarized along the \vec{x} direction. In some implementations, a portion of resonators on the metasurface are oriented on the metasurface at a first angle with respect to an axis of the dielectric substrate and another portion of the resonators are oriented on the metasurface at a second angle that is offset by +90 or −90 degrees from the first angle with respect to the axis.

FIG. 2B shows the broadband simulation of the all-dielectric metasurface. Numerical simulations were performed using the finite-element method (CST Microwave Studio) and the local phase method. The design of the m-QWP is centered at λₒ=800 nm with 40 nm bandwidth, which converts the input LP (Eₓ) to output RCP (E_{RCP}) or LCP (E_{LCP}) light depending on the rotation range of the resonator with respect to the input LP. The m-QWP covers the bandwidth of the incident laser pulse needed for AO-HDS centered at λₒ=800 nm. The ratio |E_{y}|/|Eₓ| is ˜1 and the corresponding phase difference (ϕ_{y}-ϕₓ) between E_{y} and Eₓ is ˜π/2 over the bandwidth of the optical pulse needed for AO-HDS. FIG. 2C shows the real part of Eₓ and E_{y} inside the metasurface; as the incident field Eₓ passes through the resonator, half of the incident electric field couples into the E_{y} with a phase difference ϕ_{y}-ϕₓ=π/2. The m-QWP structure is fabricated by top-down nano-manufacturing methods. FIGS. 2D-E show example scanning electron microscope (SEM) images of the RCP (FIG. 2D) and LCP m-QWP (FIG. 2E) in a top view, demonstrating successful fabrication of the metasurface. The m-QWP in FIG. 2D generates RCP and the m-QWP in FIG. 2E generates LCP for a linearly polarized input light.

To independently characterize and evaluate the performance of the polarization state of the light transmitted out of the m-QWP, Stokes parameters (I, M, C, S) were used

$$S = {\vert {E}_{LCP} \vert}^{2} - {\vert {E}_{RCP} \vert}^{2} \qquad ( 1 )$$

where S=1 is for an ideal LCP and S=−1 is for an ideal RCP. To enable a quantitative comparison between disclosed devices and ideal cases, FIGS. 2F-G show example polarization ellipses for ideal, simulated, and fabricated m-QWP generating RCP (FIG. 2F) and LCP (FIG. 2G). These polarization ellipses are extracted from the Stokes parameters averaged over the entire wavelength range of the femtosecond laser pulse. The conversion efficiency of input linear polarization to output circular polarization, for simulated and fabricated m-QWP, is up to 91% and 97% respectively in comparison with commercial QWP, which has a conversion efficiency of 99%. The average transmission efficiency, for simulated and fabricated m-QWP, is up to 96% and 97% respectively, in comparison with commercial QWP, which has a transmission efficiency of 99%. Thus, a planar m-QWP, comparable in its AO-HDS performance to a commercial QWP shown in previous studies, is disclosed and can provide a compact alternative to commercial QWP. The disclosed embodiments therefore open a realm towards integrating metasurfaces and ultrafast magnetism in ferromagnetic materials, referred to herein as meta-magnetic all-optical helicity dependent switching (M⊙S).

In an example fabrication process, the m-QWPs are fabricated by a top-down etching method using a deep Silicon etching system (oxford plasma lab 100 RIE/ICP) and a resist pattern mask (ma-N series). First, a thin α-Si film is deposited on a cleaned BK7 substrate using plasma enhanced chemical vapor deposition system. Then the sub-wavelength size resist patterns are formed on it using an electron beam lithography (Vistec EBPG5200) process.

To measure the degree of CP of the light coming out of the m-QWP, an experimental Stokes polarimetry setup was employed. Following this experimental scheme, the transmitted light obeys the following relationship:

$${I}_{T} = \frac{1}{2} [ I + ( M cos 2 β - C sin 2 β ) cos 2 ( α - β ) + ( C cos 2 β - M sin 2 β ) cos δ + S sin δ ] sin 2 ( α - β ) \qquad ( 2 )$$

where δ is the retardance of the QWP, β is the angle of the QWP, and α is the angle of the polarizer P with reference to input polarization. The Stokes parameters can be extracted by measuring the change in I_{T} as a function of the linear polarizer angle, α, or the QWP angle, β. In measurements of the m-QWP, α was kept fixed at 0° with respect to the input polarization and only the QWP (Thorlabs WPQSM05-808) was axially translated. Equation (2) was then used to calculate the Stokes parameters from I_{T}.

In an example use case, a metasurface based on the disclosed technology was used to demonstrate AO-HDS in ferromagnetic, perpendicularly magnetized [Pt(0.7 nm)/Co(0.6 nm)]_{N} multilayers, where N=1 or 2 is the number of [Pt/Co] bilayers in the thin film. The perpendicularly magnetized ferromagnetic thin films were grown on glass substrates by a DC magnetron sputtering system with a base pressure of >3×10⁻⁸ Torr. These thin films possess the following structure: glass substrate/Ta(3 nm)/Pt(3 nm)/[Pt(0.7 nm)/Co(0.6 nm)]//Pt(3.7 nm), where the number of repeats is N=1 or 2. The film deposition was performed at room temperature and in an Argon (Ar) gas atmosphere. The Ar pressure during the deposition was 2.7 mTorr for all the layers.

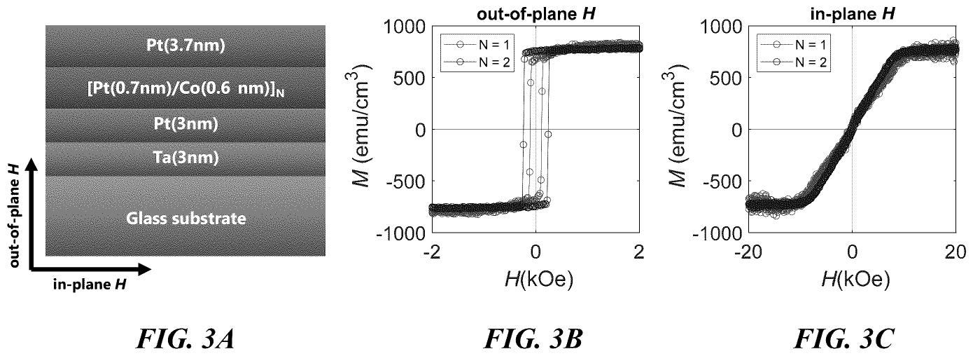

FIG. 3A shows the structure of the deposited ferromagnetic Pt/Co multilayer films, where N=1 or 2. The ferromagnetic thin films were independently characterized using the Vibrating Sample Magnetometer (VSM) option of a VersLab system (Quantum Design, Inc., San Diego, CA). By considering the spin polarization of the Pt atoms at the interfaces by the adjacent Co layers, the saturation magnetization Ms=816 emu/cm³ and the uniaxial anisotropy constant Kᵤ=4.38×10⁶ erg/cm³ were measured for N=1. For N=2, the measured saturation magnetization and uniaxial anisotropy constant were Ms=782 emu/cm³ and Kᵤ=3.82×10⁶ erg/cm³, respectively. FIGS. 3B-C show the room temperature VSM hysteresis loops measured for a magnetic field applied perpendicular and parallel to the plane of the samples, respectively. Both studied ferromagnetic films exhibit a strong perpendicular magnetic anisotropy. In the presently described use case, N=1 and N=2 were selected as they satisfy the previously determined domain size criterion for AO-HDS for these films.

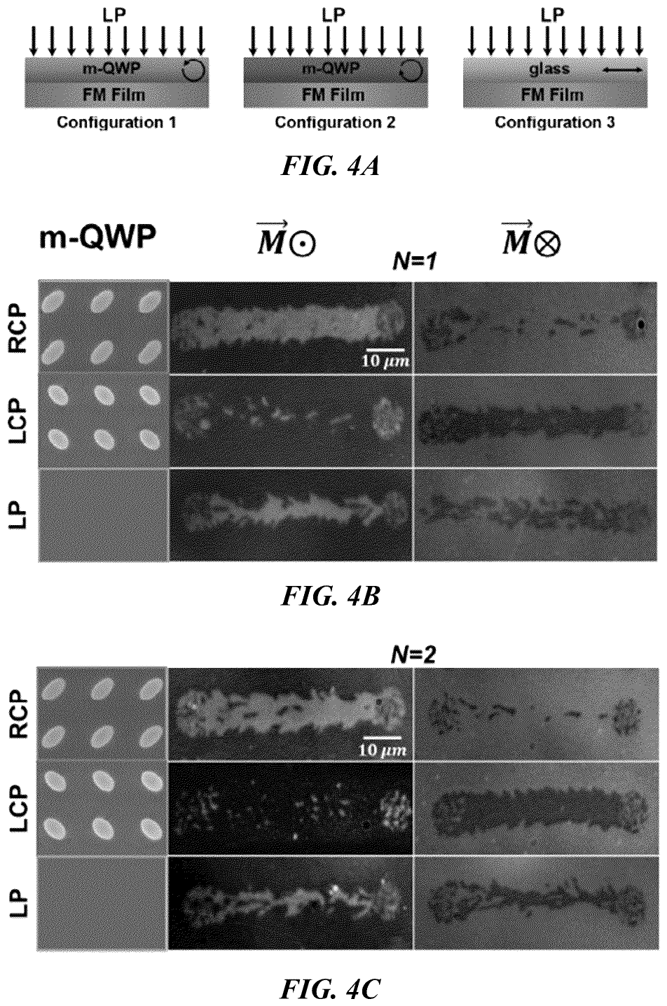

The magneto-optical response in zero applied magnetic field of the [Pt/Co]_{N} multilayers previously described to various laser polarizations was investigated. FIG. 4A shows a simplified version of three monolithic configurations based on the disclosed technology which were utilized in the investigation. In FIG. 4A, Configuration 1 shows incident LP light on RCP m-QWP, Configuration 2 shows LP light on an LCP m-QWP, and Configuration 3 shows LP light on glass (no m-QWP). FIGS. 4B and 4C show the results of Faraday imaging of [Pt/Co]_{N} with N=1 and N=2, respectively. For each sample in FIGS. 4B-C, RCP, LCP, and LP optical pulses were swept over the sample from left to right. The initial magnetization saturation is shown at the top of each column in FIGS. 4B-C, where \vec{M}└ represents in-plane magnetization and \vec{M}⊗ represents out-of-plane magnetization. The dark or white contrast in FIGS. 4B-C corresponds to the reversal to the opposite of the initial magnetization. The third row in FIGS. 4B-C are the results with removed metasurface and illumination of the ferromagnetic material with LP femtosecond optical pulses.

For AO-HDS, the helicity of the femtosecond laser pulses is controlled by the m-QWP, which transforms the LP light into the desired CP state. Using a motorized linear translation stage, the ferromagnetic sample was swept at 10 μm/s for 60 μm. The laser spot size incident on the ferromagnetic film was fixed at about 20 μm radius, while the radius of the optically switched magnetic area was 5 μm. Therefore, to emulate a monolithic device for switching in arbitrary geometries, the laser spot size and the corresponding fluence incident on the metasurface was the same as the laser spot size and the corresponding fluence incident on the ferromagnetic film. The laser fluence for N=1 and N=2 were optimized separately to achieve AO-HDS in each sample. Since the threshold power for AO-HDS increases with the repetition rate, fluence is the optimization parameter for the input laser pulse. A conventional quarter-waveplate, due to its large size and high damage threshold, offers room to maneuver around the fluence needed for AO-HDS which is not always available to some metasurfaces which generally have a smaller size and lower damage threshold. To address this issue, metasurfaces based on the disclosed technology can be fabricated to incorporate the fluence requirements needed for AO-HDS to mitigate damage to the metasurface while operating at the fluence threshold needed for AO-HDS. During the investigation presently described, the damage threshold of the fabricated m-QWP was not reached when optimizing the fluence for AO-HDS, which was confirmed by imaging the metasurface after AO-HDS. To ensure this process was indeed AO-HDS, which is reversible and then repeatable, the magnetization direction was realigned using a permanent magnet and the experiments were repeated on the same area of the ferromagnetic sample. To prevent temperature dependent magnetic susceptibility changes, all measurements in the experiments were conducted at room temperature.

For a fair comparison, the femtosecond pulses incident on the ferromagnetic material had the same fluence for all three configurations (FIG. 4A) for a particular ferromagnetic multilayer repetition, N. The dark or white contrast in FIGS. 4B-C correspond to a reversal of the initial magnetization to the other direction. The first column in FIGS. 4B-C shows example SEM images of the type of m-QWP, which will determine the incident polarization, RCP or LCP, on the ferromagnetic material and the decision on the reversal of the magnetization. The second and third columns in FIGS. 4B-C show the results for m-QWP induced RCP, m-QWP induced LCP, and LP incident on [Pt/Co] ferromagnetic thin films, where N=1 in FIG. 4A and N=2 in FIG. 4B. In the second column, the initial magnetization of the sample is into the plane, M⊙, while in the third column, the initial magnetization of the sample is out of the plane, M⊗. When the initial magnetization is M⊙, the m-QWP RCP optical pulses reverse the magnetization, as shown by the white contrast. Meanwhile, the m-QWP-induced LCP pulses do not switch the initial magnetization, as shown by the lack of difference in the contrast.

In a circularly polarized eigenbasis, LP is an equal superposition of RCP and LCP and can be expressed as

$${E}_{LP} = ( {E}_{RCP} \pm {iE}_{LCP} ) \qquad ( 3 )$$

such that when LP pulses are incident on the ferromagnetic material, one can see an average of the phenomenon experienced by the ferromagnetic material concerning optical pulses of LCP and RCP. It is worth noting that when the initial magnetization is M⊗, the opposite is observed—the m-QWP induced LCP optical pulses reverse the magnetization, as shown by the dark contrast, but the m-QWP induced RCP pulses do not switch the initial magnetization. For M⊗ as well, the LP light incident on the ferromagnetic material exhibits an average effect of LCP and RCP optical pulses.

The experimental setup was composed of two main systems: illumination and imaging. After the initial alignment of the magnetic domains using a permanent magnet, the sample was illuminated with an optical pulse train from a Ti: Sapphire laser amplifier system (Solstice from Spectra-Physics) with a central wavelength λₒ=800 nm, 35 femtosecond pulse duration at the source, and 1 kHz repetition rate. A spatially uniform, linearly polarized, quasi-collimated white light source (Thorlabs SLS201L), with a 650±40 nm bandpass filter, was incident on the sample and collected by a 40× apochromatic objective lens for observing AO-HDS in the ferromagnetic film. The light emitting diode's initial polarization rotates due to the Faraday effect depending on the sample's magnetization (M⊗ or M⊙). The clockwise or anti-clockwise direction of light polarization rotation depends on the orientation of the magnetization inside the sample and on the analyzer angle. A monochromatic CMOS camera enables the impact of these different magnetization orientations on the sample to be captured. A 50/50 beam-splitter is used to overlap the imaging source and the laser beam, allowing for direct imaging of magnetization after the laser excitation. It has been observed that magnetization has maintained the switched up/down state for at least 6 months. In some implementations of the disclosed technology, the magnetization can be maintained in a switched up/down state in an unperturbed environment for longer than 6 months. This was demonstrated by performing more than 1500 cycles on a single sample, and observing no degradation or change in the process of AO-HDS.

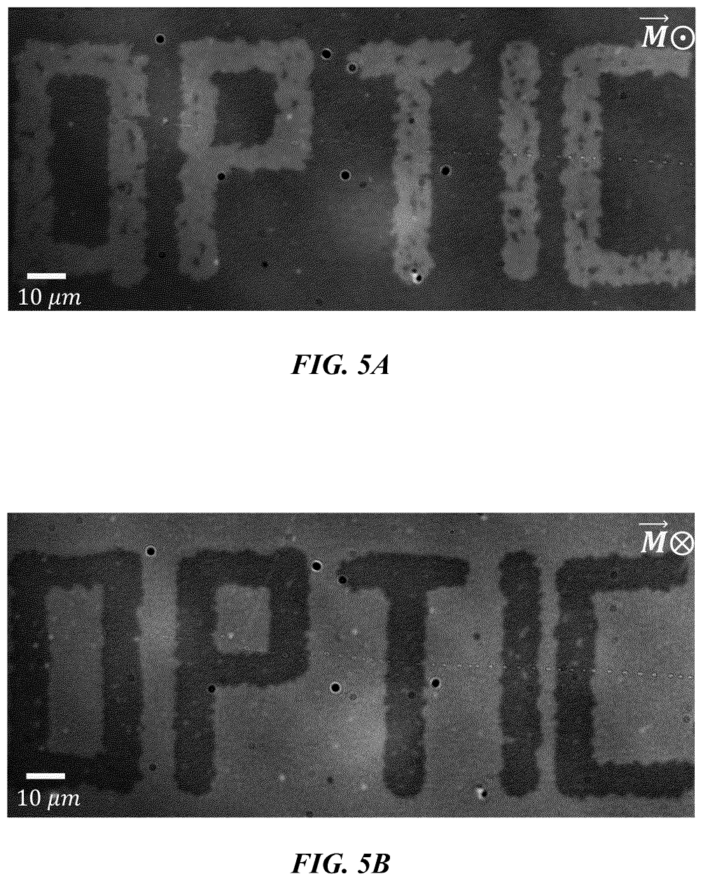

To further demonstrate the m-QWP functionality, the same experimental setup previously described was used to show that the m-QWP can switch the magnetization in arbitrary geometries. FIGS. 5A-5B show examples of such arbitrary geometry meta-magnetic AO-HDS based on the disclosed technology, in which “OPTIC” is written using m-QWP on an N=1 ferromagnetic material. To do this, a 2D motorized translation stage and an external optical shutter to block the optical pulses when transitioning from one alphabet to the other were employed and all controlled using MATLAB. In some implementations, the external optical shutter is configured to block/unblock the optical pulses such that m-QWP induced RCP or LCP light is incident upon the ferromagnetic medium at one or more predetermined times. The line scans first optimized the laser fluence and translation stage speed as in FIG. 4. The optical shutter and the translation stages were then appropriately automated to block/unblock the optical pulse and translate it into the desired geometry. The entire process of writing the word “OPTIC” took about 5 minutes, and the laser stayed on the m-QWP without damaging it. The measured damage threshold of the example metasurface is around 76.3 mJ/cm³. The present result supports the ability of m-QWPs fabricated in accordance with the disclosed technology to withstand long exposures to high-power lasers. Since AO-HDS relies on the fluence of the femtosecond laser pulses, m-QWPs based on the disclosed technology are fabricated to tolerate the fluence needed for AO-HDS without any damage to the m-QWPs.

In some implementations of the disclosed technology, laser light is scanned in a direction along the m-QWP such that the laser light is incident upon at least one of a first set of resonators and a second set of resonators disposed on the m-QWP. The magnetization of the magnetic medium can be modified at one or more locations based on the direction of the scanning and whether the laser light is incident upon the first set of resonators or the second set of resonators. In scenarios where a writing pattern on the magnetic medium that requires use of both LCP and RCP light desired, an optical shutter positioned in front of the laser may be employed as an “on/off switch” to control laser pulses while the position of the laser is moved to a different incident area upon the metasurface. In some implementations of writing using both LCP and RCP light, the approach may involve physically decoupling the metasurface from the magnetic medium and then translating or aligning them accordingly such that laser light is incident upon the desired set of resonators for generating LCP or RCP light. For example, a writing process may involve causing laser light to be incident upon a first set of resonators on the m-QWP which are configured to produce RCP light upon illumination by the laser, receiving the m-QWP-induced RCP light at a region on the magnetic medium such that magnetization at the region is switched, positioning the metasurface with respect to the magnetic medium (or vice versa) such that the region is aligned with a second set of resonators on the m-QWP which are configured to produce LCP light upon illumination by the laser, and receiving the m-QWP induced LCP light at the region such that magnetization at the region is reversed.

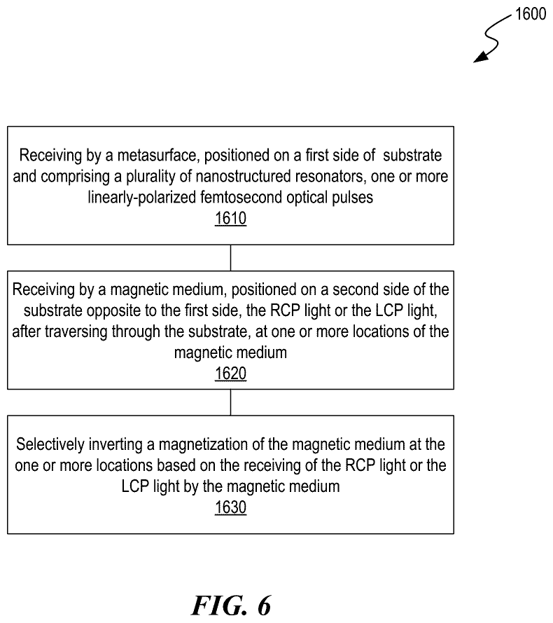

FIG. 6 shows a flow chart of an example method 1600 for switching magnetization based on the disclosed technology. At operation 1610, the method 1600 comprises receiving by a metasurface, positioned on a first side of a substrate and comprising a plurality of nanostructured resonators, one or more linearly-polarized femtosecond optical pulses. In some implementations, a first portion of the plurality of nanostructured resonators is configured to produce right circularly polarized (RCP) light upon illumination by the one or more linearly-polarized femtosecond optical pulses, and a second portion of the plurality of nanostructured resonators is configured to produce left circularly polarized (LCP) light upon illumination by the one or more linearly-polarized femtosecond optical pulses. At operation 1620, the method 1600 comprises receiving by a magnetic medium, positioned on a second side of the substrate opposite to the first side, the RCP light or the LCP light, after traversing through the substrate, at one or more locations of the magnetic medium. At operation 1630, the method 1600 comprises selectively inverting a magnetization of the magnetic medium at the one or more locations based on the receiving of the RCP light or the LCP light by the magnetic medium.

The present patent document discloses various example embodiments and experimental demonstrations related to a monolithic multilayer nanostructure capable of achieving high-speed optical helicity-dependent switching using femtosecond meta-circularly polarized optical pulses at room temperature. Among other features and benefits, the monolithic meta-magnetic platforms disclosed herein provide a practical route to reform current data storage and information processing technologies in complex systems, holding great promise for cutting-edge applications in information, spintronics, quantum computing, sensing, and memory storage devices.

Various operations disclosed herein can be implemented using a processor/controller is configured to include, or be couple to, a memory that stores processor executable code that causes the processor/controller carry out various computations and processing of information. The processor/controller can further generate and transmit/receive suitable information to/from the various system components, as well as suitable input/output (IO) capabilities (e.g., wired or wireless) to transmit and receive commands and/or data.

Various information and data processing operations described herein may be implemented in one embodiment by a computer program product, embodied in a computer-readable medium, including computer-executable instructions, such as program code, executed by computers in networked environments. A computer-readable medium may include removable and non-removable storage devices including, but not limited to, Read Only Memory (ROM), Random Access Memory (RAM), compact discs (CDs), digital versatile discs (DVD), etc. Therefore, the computer-readable media that is described in the present application comprises non-transitory storage media. Generally, program modules may include routines, programs, objects, components, data structures, etc. that perform particular tasks or implement particular abstract data types. Computer-executable instructions, associated data structures, and program modules represent examples of program code for executing steps of the methods disclosed herein. The particular sequence of such executable instructions or associated data structures represents examples of corresponding acts for implementing the functions described in such steps or processes.

Only a few implementations and examples are described and other implementations, enhancements and variations can be made based on what is described and illustrated in this patent document.

What is claimed:

1. A magnetic memory device, comprising:
a substrate;
a magnetic medium; and
a metasurface comprising a plurality of nanostructured resonators, wherein:
the metasurface is positioned on a first side of the substrate,
the magnetic medium is positioned on a second side of the substrate opposite to the first side,
the substrate, the magnetic medium and the metasurface form a monolithic structure,
the metasurface is configured to receive one or more linearly-polarized femtosecond optical pulses,
a first portion of the plurality of nanostructured resonators is configured to produce right circularly polarized (RCP) light upon illumination by the one or more linearly-polarized femtosecond optical pulses,
a second portion of the plurality of nanostructured resonators is configured to produce left circularly polarized (LCP) light upon illumination by the one or more linearly-polarized femtosecond optical pulses, and
the magnetic medium is configured to receive the RCP light or the LCP light, after traversing through the substrate, at one or more locations of the magnetic medium to enable selective inverting of a magnetization of the magnetic medium at the one or more locations.

2. The magnetic memory device of claim 1, wherein each of the plurality of nanostructured resonators is of an elliptical shape, wherein the elliptical shape has a semi-major axis, a semi-minor axis, and a height that are each less than 400 nm.

3. The magnetic memory device of claim 1, wherein the plurality of nanostructured resonators are configured in an array having a first periodicity along a first direction and a second periodicity along a second direction, wherein the first periodicity and the second periodicity are substantially equal to each other.

4. The magnetic memory device of claim 3, wherein the first direction and the second direction are perpendicular to one another.

5. The magnetic memory device of claim 1, wherein the first portion of the plurality of nanostructured resonators are oriented on the metasurface at a first angle with respect to an axis of the substrate, wherein the second portion of the plurality of nanostructured resonators are oriented on the metasurface at a second angle that is offset by +90 or −90 degrees from the first angle with respect to the axis.

6. The magnetic memory device of claim 1, wherein the magnetic medium is a thin film multilayer comprising a number N of repetitions of a bilayer comprising two magnetic materials.

7. The magnetic memory device of claim 6, wherein the two magnetic materials are ferromagnetic, wherein the bilayer is perpendicularly magnetized.

8. The magnetic memory device of claim 1, wherein the magnetic memory device is compatible for integration with complementary metal-oxide semiconductor (CMOS) materials.

9. The magnetic memory device of claim 1, wherein the magnetic medium is part of an information processing or data storage medium.

10. The magnetic memory device of claim 1, wherein the magnetization is oriented along an initial direction, wherein the RCP light or the LCP light causes the magnetization to orient along another direction that is different from the initial direction.

11. A method for switching magnetization, comprising:
receiving by a metasurface, positioned on a first side of a substrate and comprising a plurality of nanostructured resonators, one or more linearly-polarized femtosecond optical pulses, wherein:
a first portion of the plurality of nanostructured resonators is configured to produce right circularly polarized (RCP) light upon illumination by the one or more linearly-polarized femtosecond optical pulses, and
a second portion of the plurality of nanostructured resonators is configured to produce left circularly polarized (LCP) light upon illumination by the one or more linearly-polarized femtosecond optical pulses;
receiving by a magnetic medium, positioned on a second side of the substrate opposite to the first side, the RCP light or the LCP light, after traversing through the substrate, at one or more locations of the magnetic medium; and
selectively inverting a magnetization of the magnetic medium at the one or more locations based on the receiving of the RCP light or the LCP light by the magnetic medium.

12. The method of claim 11, further comprising:
positioning the metasurface or the magnetic medium such that the one or more locations of the magnetic region are aligned with the first portion of the plurality of nanostructured resonators or the second portion of the plurality of nanostructured resonators, wherein the receiving and the selectively inverting are based on the positioning.

13. The method of claim 11, wherein the first portion of the plurality of nanostructured resonators are oriented on the metasurface at a first angle with respect to an axis of the substrate, wherein the second portion of the plurality of nanostructured resonators are oriented on the metasurface at a second angle that is offset by +90 or −90 degrees from the first angle with respect to the axis.

14. The method of claim 11, wherein the magnetic medium is a thin film multilayer comprising a number N of repetitions of a bilayer comprising two magnetic materials.

15. The method of claim 14, wherein the magnetic materials are ferromagnetic, wherein the bilayer is perpendicularly magnetized.

16. The method of claim 11, wherein the substrate, the metasurface, and the magnetic medium form a monolithic device, wherein the monolithic device is compatible for integration with complementary metal-oxide semiconductor (CMOS) materials.

17. The method of claim 11, wherein the magnetic medium is part of an information processing or data storage medium.

18. The method of claim 11, wherein the magnetization is orientated along an initial direction, wherein the selectively inverting comprises causing the magnetization to orient along another direction that is different from the initial direction.

19. The method of claim 18, wherein the magnetic medium has a perpendicular magnetic anisotropy, wherein the initial direction is along an in-plane or out-of-plane direction with respect to a surface of the magnetic medium due to the perpendicular magnetic anisotropy.

20. The method of claim 11, wherein the linearly-polarized femtosecond optical pulses are generated by a light source, wherein an optical shutter is positioned in front of the light source, and wherein the optical shutter is configured to regulate propagation of the linearly-polarized femtosecond optical pulses towards the metasurface such that the RCP light or the LCP light is received by the magnetic medium at one or more predetermined times.
